(19) United States
(12) Patent Application Publication
(10) Pub. No.: US 2014/0247570 A1
(43) Pub. Date: Sep. 4, 2014

(54) CIRCUIT BOARD STRUCTURE HAVING ELECTRONIC COMPONENTS EMBEDDED THEREIN AND METHOD OF FABRICATING THE SAME

(71) Applicant: Unimicron Technology Corporation, Taoyuan (TW)

(72) Inventors: Doau-Tzu Wang, Taoyuan (TW); Chih-Jung Chen, Taoyuan (TW)

(21) Appl. No.: 13/912,557

(22) Filed: Jun. 7, 2013

(30) Foreign Application Priority Data
Mar. 1, 2013 (TW) 102107230

(51) Int. Cl. H05K 1/18; H05K 3/32

(52) U.S. Cl. CPC H05K 1/184; H05K 3/32
USPC 361/760; 29/837

(57) ABSTRACT

A circuit board structure having electronic components embedded therein and a method of fabricating the same are provided. The circuit board structure includes a substrate having a first circuit layer formed on at least one surface thereof, electronic components electrically connected to the first circuit through a metallic connector, a first dielectric layer formed on the first circuit layer of the substrate and having a plurality of dielectric layer cavities for the first circuit layer to be exposed therefrom and the electronic components to be received therein, a plurality of vias, a second dielectric layer formed on the first dielectric layer and the electronic components and having a plurality of dielectric layer vias for the electronic components to be exposed therefrom and the vias to be formed therein, and a second circuit layer formed on the second dielectric layer and electrically connected to the electronic components through the vias.

### BACKGROUND OF THE INVENTION

1. Field of the Invention

This invention relates to circuit board structures and methods of fabricating the same, and, more particularly, to a circuit board structure having an electronic components embedded therein and a method of fabricating the circuit board structure.

2. Description of Related Art

With the rapid progress of the semiconductor packaging technology, a variety of package types, in addition to the conventional wire bonding and flip chip packages, have been brought to the market. For example, an electronic component can be embedded in and electrically connected to a package substrate. Such a package reduces the size of a circuit board structure and improves the electrical functionalities, and is becoming popular in the art.

FIGS. 1A to 1G are cross-sectional views illustrating a method of fabricating a circuit board structure having electronic components embedded therein according to the prior art.

As shown in FIG. 1A, a substrate 10 having a first surface 10a, a second surface 10b opposing the first surface 10a, and cavities 100 penetrating the first surface 10a and the second surface 10b is provided.

As shown in FIG. 1B, an adhesive sheet 11 is disposed on the second surface 10b and covers one end of each of the cavities 100.

As shown in FIG. 1C, a positioning frame 12 is disposed on the first surface 10a to position the substrate 10.

As shown in FIG. 1D, electronic component 13s are disposed on the adhesive sheet 11 and in the cavities 100. Each of the electronic components 13 has a first active surface 13a and a second active surface 13b opposing the first active surface 13a. First electrode pads 131a and second electrode pads 131b are disposed on the first active surface 13a and the second active surface 13b, respectively, and the first active surface 13a and the first electrode pads 131a are exposed from the first surface 10a.

As shown in FIG. 1E, the adhesive sheet 11 and the positioning frame 12 are removed, a first dielectric layer 14a and a first metallic layer 15a are laminated on the first surface 10a sequentially, and a second dielectric layer 14b and a second metallic layer 15b are laminated on the second surface 10b sequentially.

As shown in FIG. 1F, first vias 141a and second vias 141b are formed in the first dielectric layer 14a and the second dielectric layer 14b, respectively, and the first metallic layer 15a and the second metallic layer 15b are patterned to form a first circuit layer 151a and a second circuit layer 151b, respectively.

As shown in FIG. 1G, a first built-up structure 16a and a second built-up structure 16b are formed on the first dielectric layer 14a and second dielectric layer 14b, respectively.

However, only one layer of electronic components can be embedded in the circuit board structure according to the prior art, and there are an even number of circuit layers, which adversely affect the design of multi-function electronic products and are contrary to the compact-size and low-profile requirements for electronic products. Such a conventional circuit board structure can be applied to a low-end product.

Therefore, how to solve the problems of the prior art is becoming an urgent issue in the art.

### SUMMARY OF THE INVENTION

In view of the problems of the prior art, the present invention provides a circuit board structure having electronic components embedded therein, the circuit board structure comprising: a substrate having a first circuit layer formed on at least one surface thereof; a first dielectric layer formed on the first circuit layer of the substrate and having a plurality of dielectric layer cavities for the first circuit layer to be partially exposed therefrom; a plurality of electronic components disposed in dielectric layer cavities and electrically connected to the first circuit layer through a metallic connector, a first portion of the electronic components being erectly disposed in the dielectric layer cavities, and a second portion of the electronic components being lain in the dielectric layer cavities; a second dielectric layer formed on the first dielectric layer and the electronic components and having a plurality of dielectric layer vias for the electronic components to be exposed therefrom, a first portion of the dielectric layer vias from which the second portion of the electronic components are exposed therefrom being less in depth than a second portion of the dielectric layer vias from which the second portion of the electronic components are exposed; a plurality of vias formed in the dielectric layer vias, a first portion of the vias corresponding to the first portion of the electronic components being less in depth than a second portion of the vias corresponding to the second portion of the electronic components; and a second circuit layer formed on the second dielectric layer and electrically connected to the electronic components through the vias.

The present invention further provides a method of fabricating a circuit board structure having electronic components embedded therein, the method comprising: forming a first dielectric layer a first circuit layer formed on at least one surface of a substrate, the first dielectric layer having a plurality of dielectric layer cavities for the first circuit layer to be exposed therefrom; disposing a plurality of electronic components in the dielectric layer cavities and electrically connecting the electronic components to the first circuit layer through a metallic connector, allowing a first portion of the electronic components to be erectly disposed in the dielectric layer cavities, and a second portion of the electronic components being lain in the dielectric layer cavities; and forming a second dielectric layer and a second circuit layer on the first dielectric layer and the electronic components sequentially and forming a plurality of vias in the second dielectric layer, so as for the second circuit layer to be electrically connected to the electronic components through the vias, wherein a first portion of the vias corresponding to the first portion of the electronic components is less in depth than a second portion of the vias corresponding to the second portion of the electronic components.

According to the present invention, since the electronic components are erectly disposed or lain in a circuit board and are stacked on one another, the present invention can achieve the effect of connecting the electronic components in series and in parallel. Therefore, the design flexibility of the circuit board is enhanced, and the high complexity, powerful functionalities, and custom-made requirements for product design are met.

### BRIEF DESCRIPTION OF DRAWINGS

The invention can be more fully understood by reading the following detailed description of the preferred embodiments, with reference made to the accompanying drawings, wherein:

FIGS. 1A to 1G are cross-sectional views illustrating a method of fabricating a circuit board structure having an electronic components embedded therein according to the prior art;

FIGS. 2A to 2G are cross-sectional views illustrating a method of fabricating a circuit board structure having an electronic components embedded therein of a first embodiment according to the present invention, wherein FIG. 2G′ is another embodiment of FIG. 2G; and

FIGS. 3A to 3G are cross-sectional views illustrating a method of fabricating a circuit board structure having an electronic components embedded therein of a second embodiment according to the present invention, wherein FIG. 3G′ is another embodiment of FIG. 3G.

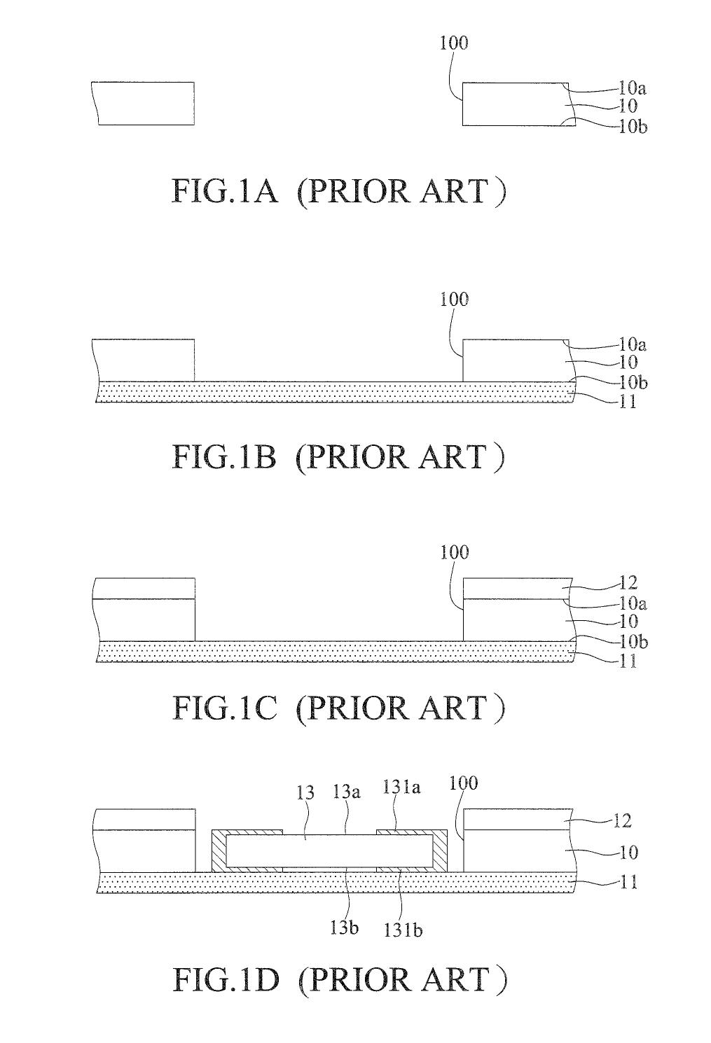

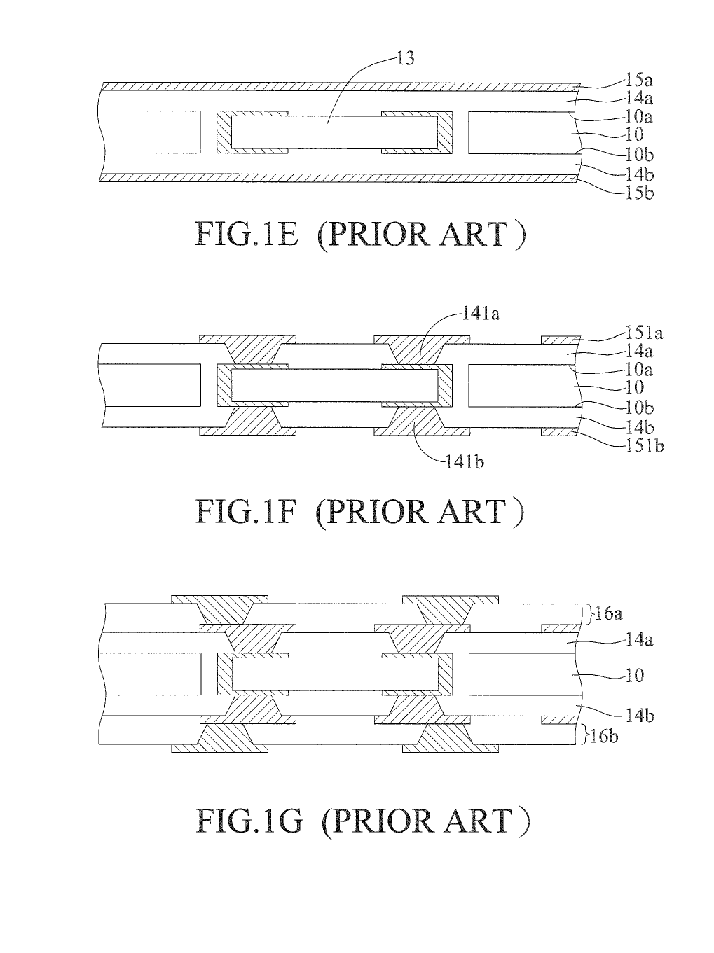

### DETAILED DESCRIPTION OF THE INVENTION

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawings. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

### FIRST EMBODIMENT

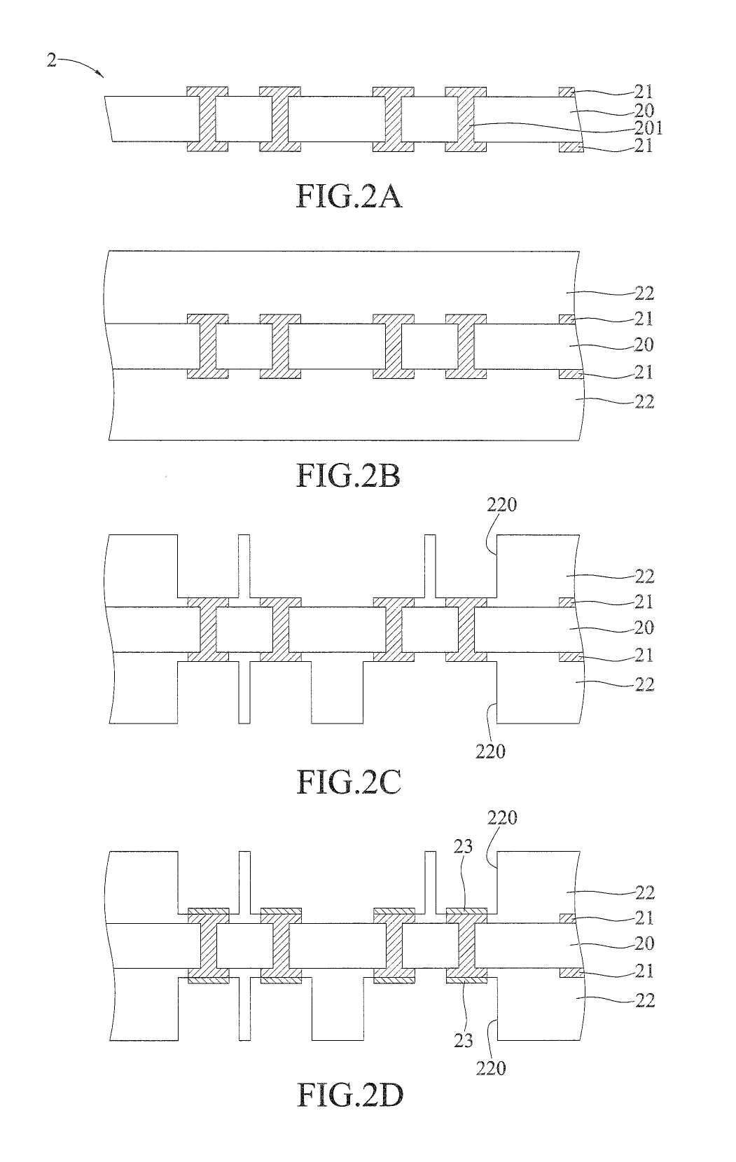

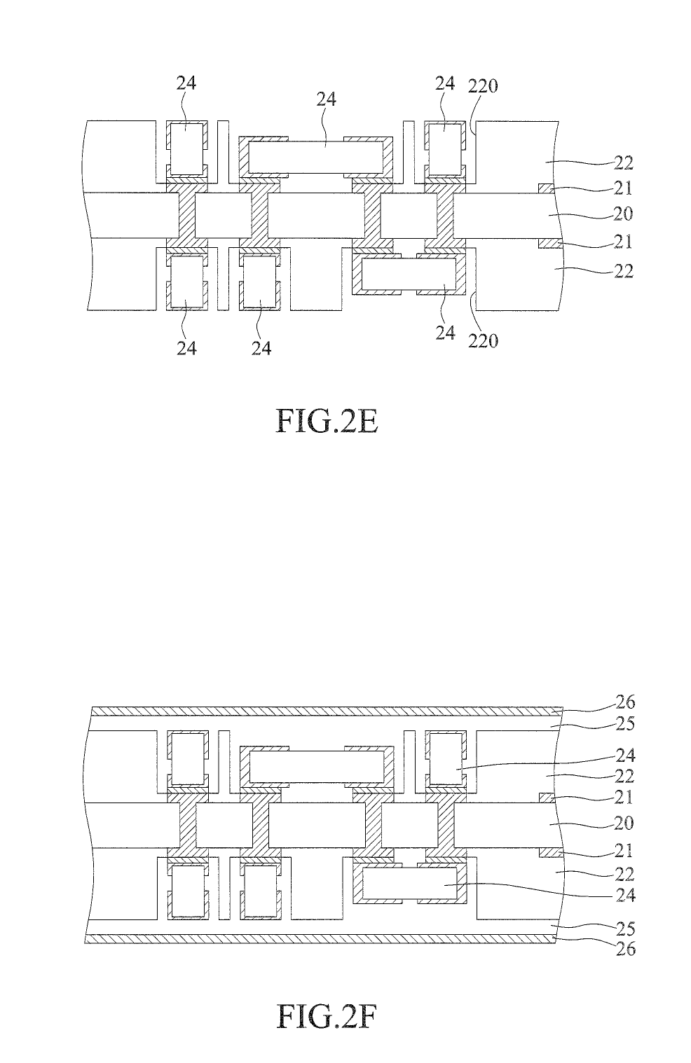

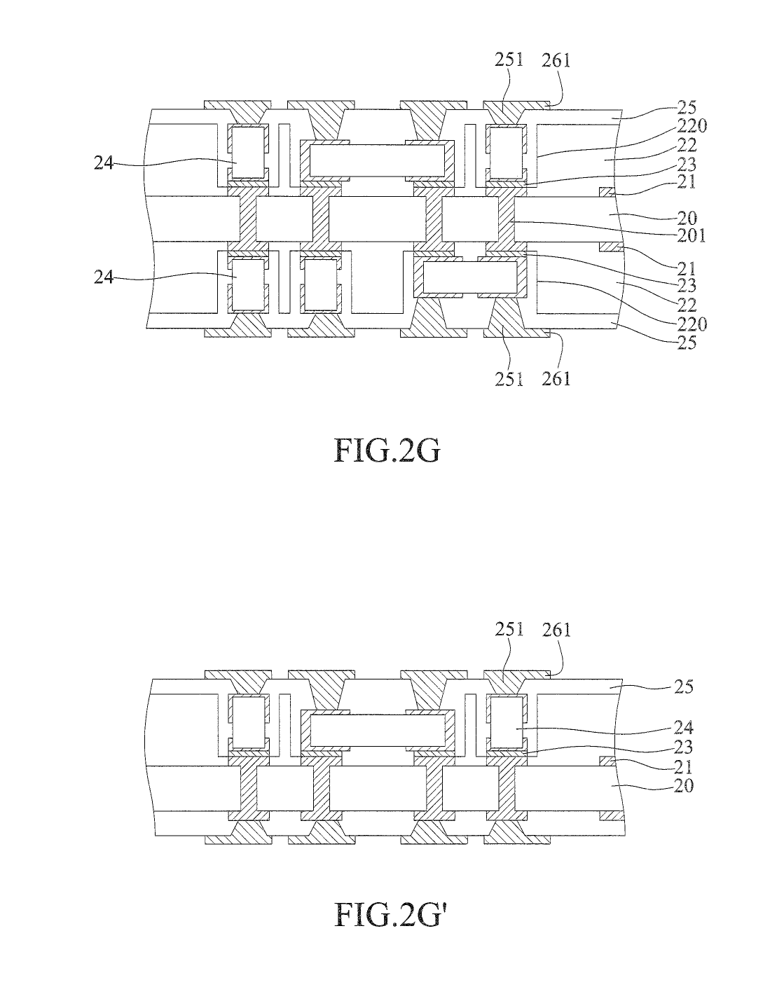

FIGS. 2A to 2G are cross-sectional views illustrating a circuit board structure having electronic components embedded therein of a first embodiment according to the present invention, wherein FIG. 2G′ is another embodiment of FIG. 2G.

As shown in FIG. 2A, a substrate 2 is composed of a core carrier board 20; a plurality of conductive through holes 201 penetrating two surfaces of the core carrier board 20; and a first circuit layer 21 formed on two opposing surfaces of the core carrier board 20 and electrically connected to the conductive through holes 201.

As shown in FIG. 2B, a first dielectric layer 22 is formed on two opposing surfaces of the substrate 2. The first dielectric layer 22 is made of a prepreg material.

As shown in FIG. 2C, a portion of the first dielectric layer 22 is removed by a laser burning method to form a plurality of dielectric layer cavities 220 for the first circuit layer 21 to be exposed therefrom.

As shown in FIG. 2D, a metallic connector 23 is formed on the exposed portion of the first circuit layer 21 by a screen printing method. The metallic connector 23 is made of silver paste, copper paste or conductive metal adhesive.

As shown in FIG. 2E, a plurality of electronic components 24 are disposed in the dielectric layer cavities 220, and electrically connected in series or parallel to the first circuit layer 21 through the metallic connector 23. A first portion of the electronic components 24 are erectly disposed in the dielectric layer cavities 220, while a second portion of the electronic components 24 are lain in the dielectric layer cavities 220. And each of the dielectric layer cavities 220 has a length and a width corresponding to a corresponding one of the electronic components 24 received therein. In an embodiment, an electronic component 24 or a plurality of electronic components 24 can be used. In an embodiment, the electronic components 24 are capacitors such as multi-layer ceramic capacitor (MLCC).

As shown in FIG. 2F, a second dielectric layer 25 and a metallic layer 26 are formed on the first dielectric layer 22 and the electronic components 24 sequentially.

As shown in FIG. 2G, a plurality of vias 251 are formed in the second dielectric layer 25, and the metallic layer 26 is patterned to form a second circuit layer 261. The second circuit layer 261 is electrically connected to the electronic components 24 through the vias 251 in the second dielectric layer 25. A first portion of the vias 251 corresponding to the first portion of erectly disposed electronic components 24 is less in depth than a second portion of the vias 251 corresponding to the second portion of the electronic components 24. A circuit board structure having electronic components embedded therein is thus obtained.

Alternatively, as shown in FIG. 2G′, only one side of the substrate 2 is formed with the metallic connector 23 and provided with the electronic components 24, which can be understood by persons having ordinary skill in the art, further description thereof hereby omitted.

### SECOND EMBODIMENT

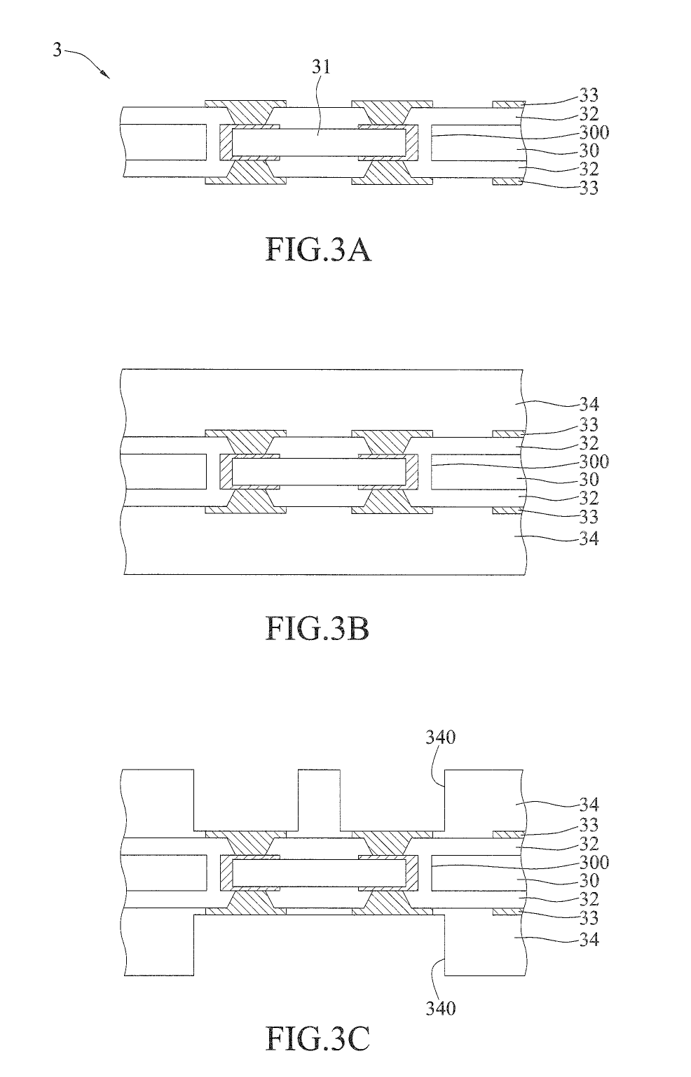

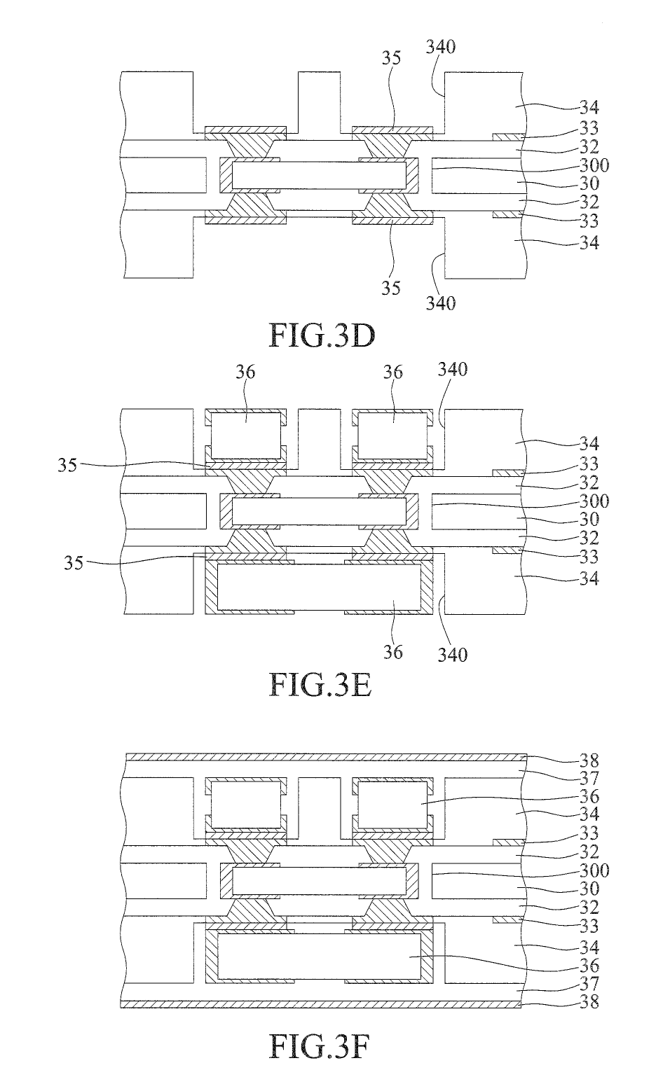

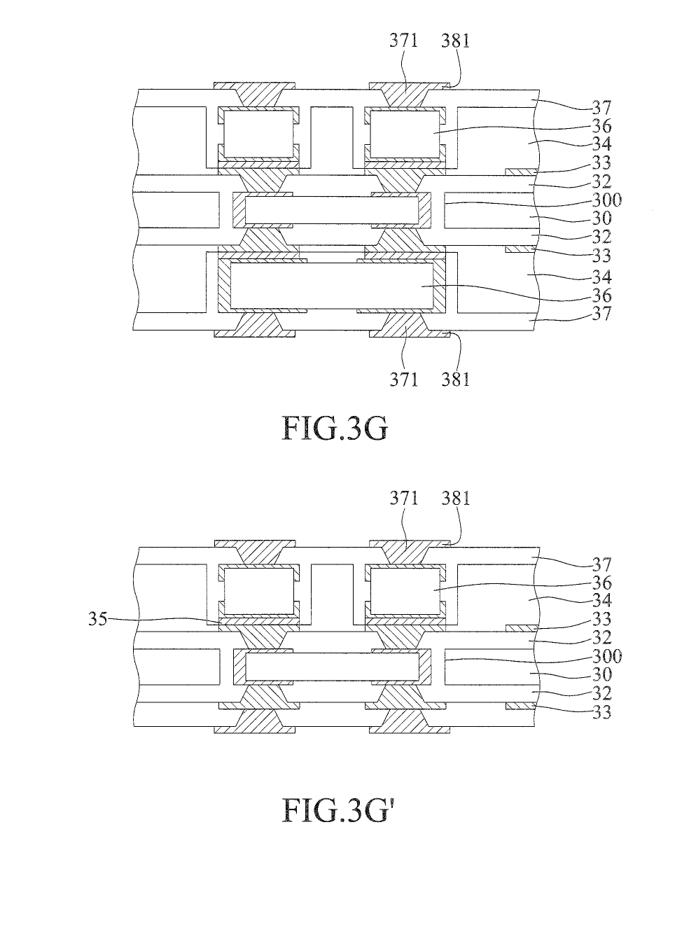

FIGS. 3A to 3G are cross-sectional views illustrating a method of fabricating a circuit board structure having electronic components embedded therein of a second embodiment according to the present invention, wherein FIG. 3G′ is another embodiment of FIG. 3G.

As shown in FIG. 3A, a substrate 3 is composed of a core carrier board 30 having cavities 300 penetrating two opposing surfaces thereof; embedded electronic components 31 disposed in the cavities 300; a core dielectric layer 32 formed on the two surfaces of the core carrier board 30 and the embedded electronic components 31; and a first circuit layer 33 formed on the core dielectric layer 32 and electrically connected to the embedded electronic components 31. In an embodiment, the embedded electronic components 31 are capacitors such as multi-layer ceramic capacitors (MLCC).

As shown in FIG. 3B, a first dielectric layer 34 is formed on two opposing surfaces of the substrate 3. The first dielectric layer 34 is made of a prepreg material.

As shown in FIG. 3C, a portion of the first dielectric layer 34 is removed by the laser burning method to form a plurality of dielectric layer cavities 340 for the first circuit layer 33 to be exposed therefrom.

As shown in FIG. 3D, a metallic connector 35 is formed on the exposed portion of the first circuit layer 33 by a screen printing method. In an embodiment, the metallic connector 35 is made of silver paste, copper paste or conductive metal adhesive.

As shown in FIG. 3E, a plurality of electronic components 36 are disposed in the dielectric layer cavities 340, the electronic components 36 are electrically connected in series or parallel to the first circuit layer 33 through the metallic connector 35, a first portion of the electronic components 36 are erectly disposed in the dielectric layer cavities 340, a second portion of the electronic components 36 are lain in the dielectric layer cavities 340, and each of the dielectric layer cavities 340 has a length and a width corresponding to a corresponding one of electronic components 36 received therein. In an embodiment, only an electronic component 24 or a plurality of the electronic components 36 can be used. In an embodiment, the electronic components 36 are capacitors such as multi-layer ceramic capacitor (MLCC).

As shown in FIG. 3F, a second dielectric layer 37 and a metallic layer 38 are formed on the first dielectric layer 34 and the electronic components 36 sequentially.

As shown in FIG. 3G, a plurality of vias 371 are formed in the second dielectric layer 37, the metallic layer 38 is patterned to form a second circuit layer 381, and the second circuit layer 381 is electrically connected to the electronic components 36 through the vias 371 in the second dielectric layer 37. A circuit board structure having electronic components embedded therein is thus obtained.

Alternatively, as shown in FIG. 3G′, only one side of the substrate 3 is formed with the metallic connector 35 and provided with the electronic components 36, which can be understood by persons having ordinary skill in the art, further description thereof hereby omitted.

The present invention further provides a circuit board structure having electronic components embedded therein, having the substrate 2, 3 having a first circuit layer 21, 33 formed on at least one surface thereof; a first dielectric layer 22, 34 formed on the surface of the substrate 2, 3 and having a plurality of dielectric layer cavities 220, 340 for the first circuit layer 21, 33 to be exposed therefrom; a plurality of electronic components 24, 36 disposed in the dielectric layer cavities 220, 340 and electrically connected to the first circuit layer 21, 33 through the metallic connector 23, 35, a first portion of the electronic components 24, 36 being erectly disposed in the dielectric layer cavities 220, 340, and a second portion of the electronic components 24, 36 are lain in the dielectric layer cavities 220, 340; a second dielectric layer 25, 37 formed on the first dielectric layer 22, 34 and the electronic components 24, 36 and having a plurality of dielectric layer vias for the electronic components 24, 36 to be exposed therefrom, a first portion of dielectric layer vias corresponding to the first portion of the electronic components 24, 36 being less in depth than a second portion of the dielectric layer vias corresponding to the second portion of electronic components 24, 36; a plurality of vias 251, 371 formed in the dielectric layer vias, a first portion of vias 251, 371 corresponding to the first portion of the electronic components 24, 36 being less in depth than a second portion of the vias 251, 371 corresponding to the second portion of the electronic components 24, 36; and a second circuit layer 261, 381 formed on the second dielectric layer 25, 37 and electrically connected to the electronic components 24, 36 through the vias 251, 371.

According to the circuit board structure having the electronic components embedded therein, the substrate 2 is composed of a core carrier board 20; a plurality of conductive through holes 201 penetrating two opposing surfaces of the core carrier board 20; and the first circuit layer 21 formed on at least one surface of the core carrier board 20 and electrically connected to the conductive through holes 201. Alternatively, the substrate 3 may include: a core carrier board 30 having cavities 300 penetrating two opposing surfaces thereof; embedded electronic components 31 disposed in the cavities 300; a core dielectric layer 32 formed on the two surfaces of the core carrier board 30 and the embedded electronic components 31; and the first circuit layer 33 formed on the core dielectric layer 32 and electrically connected to the embedded electronic components 31.

According to the circuit board structure having the electronic components embedded therein, the electronic components 24, 36 is electrically connected in series or parallel to the first circuit layer 21, 33, the electronic components 24, 36 are resistors, capacitors, inductors or chips, the metallic connector 23, 35 are silver paste, copper paste or conductive metal adhesive, and each of the dielectric layer cavities 220, 340 has a length and a width corresponding to one of electronic components 24, 36 received therein.

Compared with the prior art, the present invention has a plurality of electronic components vertically or horizontally embedded in a circuit board, and the electronic components can be thus stacked on one another. Therefore, the present invention can achieve connecting the electronic components in series and in parallel. Therefore, the design flexibility of the circuit board is enhanced, and the high complexity, powerful functionalities, and custom-made requirements for product design are met.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A circuit board structure having electronic components embedded therein, the circuit board structure comprising:
a substrate having a first circuit layer formed on at least one surface thereof;
a first dielectric layer formed on the first circuit layer of the substrate and having a plurality of dielectric layer cavities for the first circuit layer to be exposed therefrom;
a plurality of electronic components disposed in the dielectric layer cavities and electrically connected to the first circuit layer through a metallic connector, a first portion of the electronic components being erectly disposed in the dielectric layer cavities, and remaining ones of the electronic components being lain in the dielectric layer cavities;
a second dielectric layer formed on the first dielectric layer and the electronic components and having a plurality of dielectric layer vias for the electronic components to be exposed therefrom, a first portion of the dielectric layer vias from which the second portion of the electronic components are exposed therefrom being less in depth than a second portion of the dielectric layer vias from which the second portion of the electronic components are exposed;
a plurality of vias formed in the dielectric layer vias, a first portion of the vias corresponding to the first portion of the electronic components being less in depth than a second portion of the vias corresponding to the second portion of the electronic components; and
a second circuit layer formed on the second dielectric layer and electrically connected to the electronic components through the vias.

2. The circuit board structure of claim 1, wherein the substrate comprises:
a core carrier board;
a plurality of conductive through holes penetrating two opposing surfaces of the core carrier board; and
the first circuit layer formed on at least one of the two opposing surfaces of the core carrier board and electrically connected to the conductive through holes.

3. The circuit board structure of claim 1, wherein the substrate comprises:
a core carrier board having cavities penetrating two opposing surfaces thereof;
embedded electronic components disposed in the cavities;
a core dielectric layer formed on the two opposing surface of the core carrier board and the embedded electronic components; and
the first circuit layer formed on the core dielectric layer and electrically connected to the embedded electronic components.

4. The circuit board structure of claim 1, wherein the electronic components are electrically connected in series or parallel to the first circuit layer.

5. The circuit board structure of claim 1, wherein the electronic components are resistors, capacitors, inductors or chips.

6. The circuit board structure of claim 1, wherein the metallic connector is silver paste, copper paste or conductive metal adhesive.

7. The circuit board structure of claim 1, wherein each of the dielectric layer cavities has a width and a length corresponding to a corresponding one of the electronic components received therein.

8. A method of fabricating a circuit board structure having electronic components embedded therein, the method comprising:
forming a first dielectric layer on a first circuit layer formed on at least one surface of a substrate, wherein the first dielectric layer has a plurality of dielectric layer cavities for the first circuit layer to be exposed therefrom;
disposing a plurality of electronic components in the dielectric layer cavities and electrically connecting the electronic components to the first circuit layer through a metallic connector, wherein a first portion of the electronic components is erectly disposed in the dielectric layer cavities, and a second portion of the electronic components is lain in the dielectric layer cavities; and
forming a second dielectric layer and a second circuit layer on the first dielectric layer and the electronic components sequentially and forming a plurality of vias in the second dielectric layer, so as for the second circuit layer to be electrically connected to the electronic components through the vias, wherein a first portion of the vias corresponding to the first portion of the electronic components is less in depth less than a second portion of the vias corresponding to the second portion of the electronic components.

9. The method of claim 8, wherein the substrate comprises:
a core carrier board;
a plurality of conductive through holes penetrating two opposing surfaces of the core carrier board; and
the first circuit layer formed on at least one of the two opposing surfaces of the core carrier board and electrically connected to the conductive through holes.

10. The method of claim 8, wherein the substrate comprises:
a core carrier board having cavities penetrating two opposing surfaces thereof;
embedded electronic components disposed in the cavities;
a core dielectric layer formed on the two opposing surfaces of the core carrier board and the embedded electronic components; and
the first circuit layer formed on the core dielectric layer and electrically connected to the embedded electronic components.

11. The method of claim 8, wherein the electronic components are electrically connected in series or parallel to the first circuit layer.

12. The method of claim 8, wherein the electronic components are resistors, capacitors, inductors or chips.

13. The method of claim 8, wherein the metallic connector is silver paste, copper paste or conductive metal adhesive.

14. The method of claim 8, wherein each of the dielectric layer cavities has a length and a width corresponding to a corresponding one of the electronic components received therein.
